(19) United States
(12) Patent Application Publication
(10) Pub. No.: US 2007/0090090 A1
(43) Pub. Date: Apr. 26, 2007

(54) Dry etching method

(76) Inventors: Koichi Nakaune, Hikari-shi (JP); Yasuhiro Nishimori, Kudamatsu-shi (JP); Toshiaki Nishida, Kudamatsu-shi (JP); Tsuyoshi Yoshida, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/345,537

(22) Filed: Feb. 2, 2006

(30) Foreign Application Priority Data
Oct. 26, 2005 (JP) 2005-311133

(51) Int. Cl. C23F 1/00; H01L 21/461; B44C 1/22; C03C 15/00

(52) U.S. Cl. 216/58; 438/706; 216/41; 438/725

(57) ABSTRACT

A surface treatment method is provided, wherein the ratio of the etching rate of a lower resist of a multilayer resist film used for forming a fine pattern to that of an inorganic intermediate layer thin film serving as a mask to control the dimension of the pattern, that is, the shoulder selection ratio, is increased in an etching treatment of a semiconductor or the like. In the surface treatment method of a semiconductor, in which an inorganic intermediate film and an upper resist film are laminated on a lower resist film, by using plasma, CO₂ containing oxygen as a primary component is added to a gas composed of nitrogen and hydrogen, so that an etching gas is prepared. Consequently, cutting of a shoulder of the inorganic intermediate layer film is reduced and a perpendicular shape is attained.

The present application is based on and claims priority of Japanese patent application No. 2005-311133 filed on Oct. 26, 2005, the entire contents of which are hereby incorporated by reference.

### BACKGROUND OF THE INVENTION

1. Field of the Invention

The present invention relates to a surface treatment apparatus and a surface treatment method of a semiconductor device. In particular, it relates to a dry etching method for etching a semiconductor surface by using plasma.

2. Description of the Related Art

Apparatuses widely used for etching and film formation of semiconductors at present are apparatuses in which plasma is used. The present invention can be widely applied to the above-described apparatuses in which plasma is used. Here, a known technology will be described with reference to an apparatus referred to as an electron cyclotron resonance (ECR) system, as an example of the known technologies. In this system, plasma is generated by a microwave in a vacuum vessel to which a magnetic field is applied from the outside. A bias voltage is applied to a sample to accelerate ions incident to the sample. This apparatus is also used for accumulating a film other than the etching.

In recent years, as semiconductors are made finer, requirements for processing technologies, e.g., lithography and dry etching, have become increasingly severe. In the field of lithography, the wavelength of exposure light is made to become a short wavelength in order to achieve high resolution, and adoption of a multilayer resist process becomes indispensable from the viewpoint of problems in reduction of the resist film thickness, deterioration of resistance to plasma, and the like. For the multilayer resist process, a three-layer resist has been reported, in which a lower layer resist having a film thickness adequate for etching a substrate film, an intermediate layer made of a thin inorganic material to form a mask pattern used in the etching of the lower resist, and a thin upper resist adequate for achieving high resolution are used in combination.

A technology, in which an etching gas primarily including NH₃ is used, has been proposed as a method for etching the above-described lower resist (refer to Japanese Unexamined Patent Application Publication No. 1-280316, for example).

Under this known condition, only the shape is controlled by adding N₂ or H₂ to NH₃, and there is a problem in that the selection ratio to the inorganic intermediate layer is not improved.

### SUMMARY OF THE INVENTION

It is an object of the present invention to provide an etching technology in which a selection ratio of a lower resist layer to a thin inorganic intermediate layer is improved to a level higher than the level in a known technology, the shoulder of the inorganic intermediate layer is not lost, and the lower resist layer is processed by etching with good dimensional controllability.

The present invention provides a dry etching method for etching an organic polymer material layer by using a compound containing at least hydrogen and nitrogen as constituent elements based on a known technology, wherein the etching is conducted by further using an additional gas including a compound containing oxygen as a primary element, so as to increase a selection ratio, in particular a shoulder selection ratio, of an intermediate layer to an inorganic thin film.

According to the present invention, in a multilayer resist film process, a lower resist layer can be etched at a high selection ratio to the inorganic thin film serving as a mask while the dimension of the mask material is maintained.

### BRIEF DESCRIPTION OF THE DRAWINGS

FIG. 1 is a conceptual diagram for explaining the entire configuration of an apparatus to which the present invention is applied.

FIG. 2 is a diagram for explaining the relationships between changes in the amount of addition of an additional gas and the etching rate of a lower resist and between changes in the amount of addition of an additional gas and the etching rate of an inorganic thin film mask material.

FIGS. 3A to 3D are sectional views for explaining a difference in shapes after etching due to a difference in the amounts of addition of an additional gas.

### DESCRIPTION OF THE PREFERRED EMBODIMENTS

The embodiments of the present invention will be described. In a method for etching an organic polymer material layer disposed on a substrate material layer by using a mask made of an inorganic intermediate layer film of the present invention, etching is conducted by using an etching gas as a primary component and an additional gas while the etching gas includes a compound containing at least nitrogen and hydrogen as constituent elements, and the additional gas is a compound containing oxygen as a constituent element.

In the above-described dry etching method of the present invention, the compound containing nitrogen and hydrogen as constituent elements includes either a mixed gas of N₂ and H₂ or NH₃, and the etching gas containing oxygen includes at least any one of CO₂, NO₂, and SO₂. When NH₃ is used as the etching gas, nitrogen N₂ is further added as the additional gas to the additional gas, e.g., CO₂, containing oxygen.

In a dry etching apparatus of the present invention in which an organic polymer material layer disposed on a substrate material layer is etching-treated by using a mask made of an inorganic intermediate layer film, a device for conducting etching by using an etching gas as a primary component and an additional gas is provided, while the etching gas includes a compound containing at least nitrogen and hydrogen as constituent elements, and the additional gas is a compound containing oxygen as a constituent element.

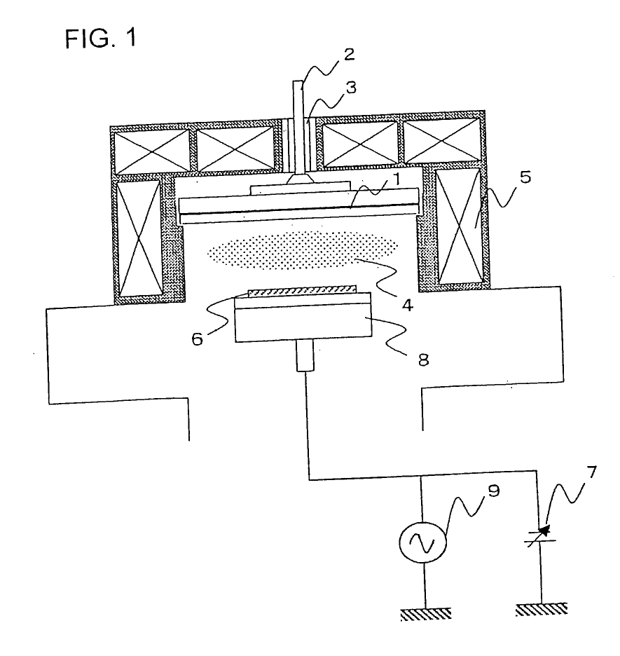

A schematic configuration of an etching apparatus used in the present invention will be described with reference to FIG. 1. The present embodiment is one example and is a UHF plasma etching apparatus in which an ultra high frequency (UHF) and a magnetic field are used as plasma generation means.

A process gas used for the etching treatment is introduced from a shower plate 1, and the pressure is adjusted at a predetermined pressure. A high-frequency wave with a frequency of 450 MHz oscillated by a UHF band high-frequency power supply (not shown in the drawing) is introduced into an etching chamber through a coaxial cable 2 and a coaxial waveguide 3. Plasma 4 is generated by an electric field formed by the high-frequency wave, and electron cyclotron resonance (ECR) is effected by the interaction with a magnetic field due to a solenoid coil 5, so that a space distribution of plasma generation density is thereby controlled.

A wafer 6 to be treated is fixed to an electrode through an electrostatic attraction force by applying a direct current voltage to a sample stage 8 from an electrostatic attraction power supply 7. A high-frequency power supply 9 is connected to the electrode, and a high-frequency electric power is applied, so that an acceleration potential in a direction perpendicular to the wafer is applied to ions in the plasma. The gas after etching is exhausted through an exhaust hole disposed on the lower portion of the apparatus by a turbopump·dry pump (not shown in the drawing).

An etching gas is specified to be NH₃, and CO₂ is introduced as an additional gas. The pressure is set at 0.4 Pa. The output of a UHF band power supply is set at 500 W, and the output of a bias power supply 9 to the wafer is set at 60 W.

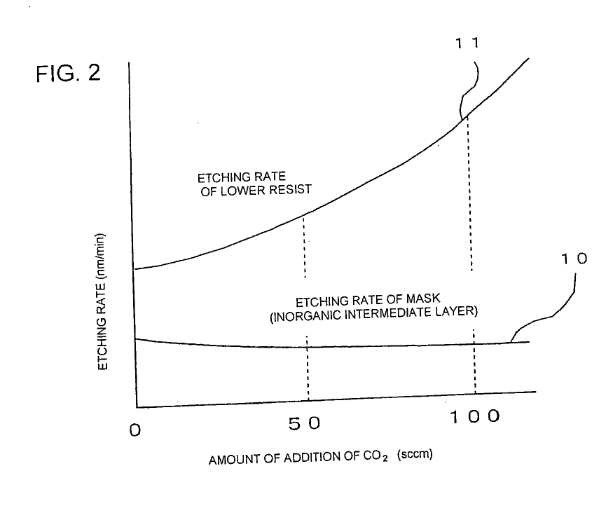

An effect of addition of CO₂ serving as an additional gas will be briefly described with reference to FIG. 2. FIG. 2 is a diagram showing the relationships between the amount of addition of CO₂ as an example of the additional gas and the etching rate 10 of an inorganic intermediate layer thin film serving as a masking material and between the amount of addition of CO₂ and the etching rate 11 of a lower resist which is a material to be etched. The etching rate of the inorganic thin film serving as the intermediate layer is decreased slightly, but is not changed to a large extent, as the additional gas CO₂ is increased. However, for the lower resist which is a material to be etched, the etching rate is increased substantially in proportion to the increase of CO₂.

The additional gas containing oxygen may be NO₂, SO₂, or the like other than CO₂, and an effect similar to that of CO₂ can be exerted.

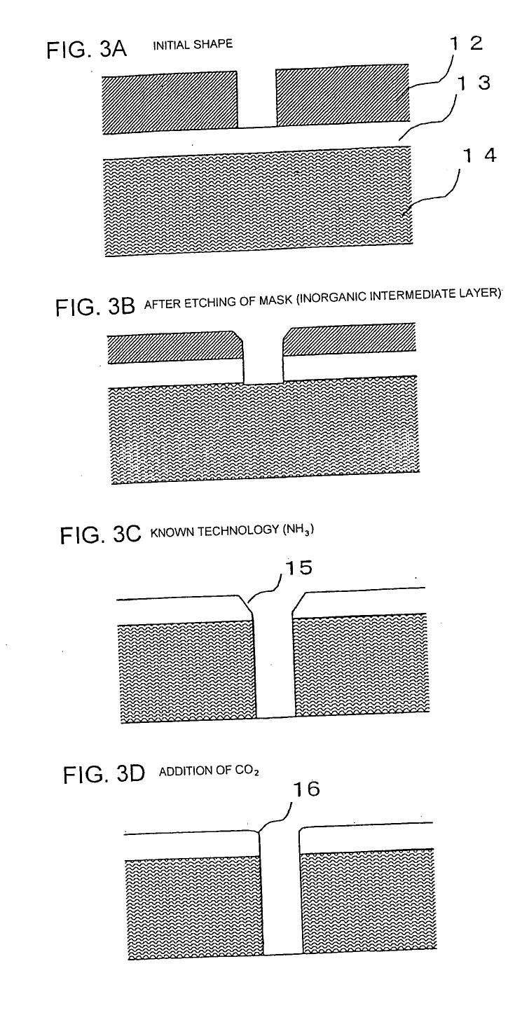

The structure of a semiconductor wafer, to which the dry etching method according to the present invention is applied, will be described with reference to FIGS. 3A to 3D. In the semiconductor wafer to which the dry etching method according to the present invention is applied, a lower resist film 14 made of an organic polymer material is disposed on a substrate material layer, although not shown in the drawing, and an inorganic intermediate layer film 13 and an (upper) resist film 12 are disposed thereon. For the lower resist film 14, novolac based photoresist, amorphous carbon, or the like is used as the organic polymer material. For the inorganic intermediate layer 13, a silicon oxide film, a silicon nitride film, or the like is used. For the (upper) resist film 12, an acrylic resin, a polynorbornene based resin, or the like is used.

The amount of addition of CO₂ in the present embodiment is changed and set at 0, 50, or 100 sccm relative to 100 sccm of NH₃. Under this condition, as the amount of addition of CO₂ is increased from 0 (FIG. 3C) to 50 (FIG. 3D) and to 100 sccm, the etching rate of the lower resist layer (organic polymer material layer) 14 is increased as shown in FIG. 2, and the selection ratio to the inorganic intermediate layer mask 13 is increased. Consequently, cutting indicated by reference numeral 15 of the mask shoulder, which occurs when the amount of addition of CO₂ is zero, can be suppressed as indicated by reference numeral 16, and an anisotropic shape can be attained.

When the amount of addition of CO₂ is 100 sccm, the shape of the lower resist layer (organic polymer material layer) becomes a somewhat side-etched shape since the amount of supply of oxygen is large. However, in this state, by adding nitrogen N₂ as an additional gas, it is also possible to attain a perpendicular shape while the etching rate is maintained because of formation of a side wall protection film resulting from an effect of the addition of nitrogen.

In the above-described embodiment, NH₃ is used as the etching gas. However, a mixed gas of N₂ and H₂ may be used. Furthermore, CO₂ is used as the etching gas containing oxygen. However, the etching gas containing oxygen may be either NO₂ or SO₂.

When NH₃ is used as the etching gas, nitrogen N₂ may be added as an additional gas further included in the additional gas, e.g., CO₂, containing oxygen.

In the present embodiment, the description is based on the assumption that the UHF type ECR plasma etching apparatus is used. However, other plasma sources cause no problem, and the apparatus is not limited to the UHF type ECR plasma etching apparatus. Therefore, the present invention can also be applied to induction type plasma apparatuses other than the microwave.

As described above, according to the present invention, the compound CO₂ configured to contain oxygen as a primary component is added as the additional gas to the etching gas, e.g., NH₃, containing hydrogen and nitrogen based on a known technology and, thereby, an anisotropic shape exhibiting a high selection ratio to the inorganic thin film serving as the intermediate layer can be attained.

What is claimed is:

1. A dry etching method in which an organic polymer material layer disposed on a substrate material layer is etched by using a mask made of an inorganic intermediate layer film, the method comprising the step of conducting etching by using an etching gas as a primary component and an additional gas while the etching gas includes a compound containing at least nitrogen and hydrogen as constituent elements, and the additional gas is a compound containing oxygen as a constituent element.

2. The dry etching method according to claim 1, wherein the compound containing nitrogen and hydrogen as constituent elements includes either a mixed gas of N₂ and H₂ or NH₃, and the etching gas containing oxygen includes at least any one of CO₂, NO₂, and SO₂.

3. The dry etching method according to claim 2, wherein NH₃ is used as the etching gas and nitrogen is further added as the additional gas.
